(19) United States
(12) Patent Application Publication
(10) Pub. No.: US 2024/0028340 A1
(43) Pub. Date: Jan. 25, 2024

(54) PARALLEL PROCESSING ARCHITECTURE WITH BIN PACKING

(71) Applicant: Ascenium, Inc., Mountain Vie, CA (US)

(72) Inventor: Peter Foley, Los Altos Hills, CA (US)

(73) Assignee: Ascenium, Inc., Mountain View, CA (US)

(21) Appl. No.: 18/236,442

(22) Filed: Aug. 22, 2023

Related U.S. Application Data
(63) Continuation-in-part of application No. 17/526,003, filed on Nov. 15, 2021.
Application No. 17/526,003 is a continuation-in-part of application No. 17/465,949, filed on Sep. 3, 2021.
(60) Provisional application No. 63/529,159, filed on Jul. 27, 2023.
(60) Provisional application No. 63/460,909, filed on Apr. 21, 2023.
(60) Provisional application No. 63/447,915, filed on Feb. 24, 2023.
(60) Provisional application No. 63/442,131, filed on Jan. 31, 2023.
(60) Provisional application No. 63/424,960, filed on Nov. 14, 2022.
(60) Provisional application No. 63/424,961, filed on Nov. 14, 2022.
(60) Provisional application No. 63/402,490, filed on Aug. 31, 2022.
(60) Provisional application No. 63/400,087, filed on Aug. 23, 2022.
(60) Provisional application No. 63/254,557, filed on Oct. 12, 2021.
(60) Provisional application No. 63/232,230, filed on Aug. 12, 2021.
(60) Provisional application No. 63/229,466, filed on Aug. 4, 2021.
(60) Provisional application No. 63/193,522, filed on May 26, 2021.
(60) Provisional application No. 63/166,298, filed on Mar. 26, 2021.
(60) Provisional application No. 63/125,994, filed on Dec. 16, 2020.
(60) Provisional application No. 63/114,003, filed on Nov. 16, 2020.
(60) Provisional application No. 63/091,947, filed on Oct. 15, 2020.
(60) Provisional application No. 63/075,849, filed on Sep. 9, 2020.

(51) Int. Cl. G06F 9/38; G06F 9/30; G06F 8/41; G06F 15/80

(52) U.S. Cl. CPC G06F 9/3836; G06F 9/30134; G06F 8/41; G06F 15/80

(57) ABSTRACT

Techniques for parallel processing based on a parallel processing architecture with bin packing are disclosed. An array of compute elements is accessed. Each compute element is known to a compiler and is coupled to its neighboring compute elements. A plurality of compressed control words is generated by the compiler. The plurality of control words enables compute element operation and compute element memory access. The compressed control words are operationally sequenced. The compressed control words are linked by the compiler. Linking information is contained in at least one field of each of the compressed control words. The compressed control words are loaded into a control word cache coupled to the array of compute elements. The compressed control words are loaded into the control word cache in an operationally non-sequenced order. The plurality of compressed control words is ordered into an operationally sequenced execution order, based on the linking information.

### RELATED APPLICATIONS

This application claims the benefit of U.S. provisional patent applications “Parallel Processing Architecture With Bin Packing” Ser. No. 63/400,087, filed Aug. 23, 2022, “Parallel Processing Architecture With Memory Block Transfers” Ser. No. 63/402,490, filed Aug. 31, 2022, “Parallel Processing Using Hazard Detection And Mitigation” Ser. No. 63/424,960, filed Nov. 14, 2022, “Parallel Processing With Switch Block Execution” Ser. No. 63/424,961, filed Nov. 14, 2022, “Parallel Processing With Hazard Detection And Store Probes” Ser. No. 63/442,131, filed Jan. 31, 2023, “Parallel Processing Architecture For Branch Path Suppression” Ser. No. 63/447,915, filed Feb. 24, 2023, “Parallel Processing Hazard Mitigation Avoidance” Ser. No. 63/460,909, filed Apr. 21, 2023, and “Parallel Processing Architecture With Block Move Support” Ser. No. 63/529,159, filed Jul. 27, 2023.

This application is also a continuation-in-part of U.S. patent application “Highly Parallel Processing Architecture With Compiler” Ser. No. 17/526,003, filed Nov. 15, 2021, which claims the benefit of U.S. provisional patent applications “Highly Parallel Processing Architecture With Compiler” Ser. No. 63/114,003, filed Nov. 16, 2020, “Highly Parallel Processing Architecture Using Dual Branch Execution” Ser. No. 63/125,994, filed Dec. 16, 2020, “Parallel Processing Architecture Using Speculative Encoding” Ser. No. 63/166,298, filed Mar. 26, 2021, “Distributed Renaming Within A Statically Scheduled Array” Ser. No. 63/193,522, filed May 26, 2021, “Parallel Processing Architecture For Atomic Operations” Ser. No. 63/229,466, filed Aug. 4, 2021, “Parallel Processing Architecture With Distributed Register Files” Ser. No. 63/232,230, filed Aug. 12, 2021, and “Load Latency Amelioration Using Bunch Buffers” Ser. No. 63/254,557, filed Oct. 12, 2021.

The U.S. patent application “Highly Parallel Processing Architecture With Compiler” Ser. No. 17/526,003, filed Nov. 15, 2021 is also a continuation-in-part of U.S. patent application “Highly Parallel Processing Architecture With Shallow Pipeline” Ser. No. 17/465,949, filed Sep. 3, 2021, which claims the benefit of U.S. provisional patent applications “Highly Parallel Processing Architecture With Shallow Pipeline” Ser. No. 63/075,849, filed Sep. 9, 2020, “Parallel Processing Architecture With Background Loads” Ser. No. 63/091,947, filed Oct. 15, 2020, “Highly Parallel Processing Architecture With Compiler” Ser. No. 63/114,003, filed Nov. 16, 2020, “Highly Parallel Processing Architecture Using Dual Branch Execution” Ser. No. 63/125,994, filed Dec. 16, 2020, “Parallel Processing Architecture Using Speculative Encoding” Ser. No. 63/166,298, filed Mar. 26, 2021, “Distributed Renaming Within A Statically Scheduled Array” Ser. No. 63/193,522, filed May 26, 2021, Parallel Processing Architecture For Atomic Operations” Ser. No. 63/229,466, filed Aug. 4, 2021, and “Parallel Processing Architecture With Distributed Register Files” Ser. No. 63/232,230, filed Aug. 12, 2021.

Each of the foregoing applications is hereby incorporated by reference in its entirety.

### FIELD OF ART

This application relates generally to parallel processing and more particularly to a parallel processing architecture with bin packing.

### BACKGROUND

Sometimes success can be as challenging as failure, if not more so. In business, government, even in art, increased demand for a product or service can cause a company to explore more effective and efficient methods of production. How can we make enough doughnuts in time for the morning rush when more customers are showing up each day? How can we gather census information from people groups who are more widely dispersed? How can we complete more sales transactions without driving our costs through the roof? As volumes of work increase, there are different methods of managing the demand. In some cases, adding more workers can address the problem. Making more doughnuts can be done by adding another baker or two. Completing the census surveys requires more census takers. Adding another checkout counter allows more sales transactions to be entered into point-of-sale terminals. Sometimes making the existing workers more efficient can be the best solution. Purchasing a doughnut making machine for the simplest items allows the bakers more time to concentrate on more complex items. Setting up an electronic census form works more quickly than a using a paper form. Buying a faster POS system or self-checkout machines can streamline the transaction process. In other cases, a combination of the two solutions may be the best approach. Increasing the number of workers and giving them more effective tools to do the job can generate more doughnuts, more completed census forms, and more completed transactions.

The same sorts of challenges occur in technology. From manufacturing more cars and trucks to delivering more short-form videos to users on a social media platform, increased volume can require more computing and storage power, as well as more efficient methods of using the computing and storage systems. Computers use many types of data to accomplish the critical missions of organizations. Commercial businesses, educational institutions, government agencies, medical facilities, research laboratories, and retail outlets all use diverse datasets to process inventory, complete sales transactions, compute shipping costs, administer exams, diagnose diseases, and so on. The organizational sets of data, or datasets, are expansive, multidimensional, and often unstructured. To perform the data processing, the organizations must commit vast financial, physical, and human resources to accomplish their missions. The stakes are high for these organizations. Handling data effectively and efficiently can lead to greater success for the enterprise, while failure can lead to decreased profitability, fewer students, lost data, and ultimately bankruptcy or acquisition by a more successful competitor. Data used by organizations can be collected using many different data collection techniques. The data can come from other organizations, customers, staff members, machine tools, regulatory agencies, and so on. While some individuals are willing data collection participants, others are unwitting subjects or even victims of the data collection. Some states require businesses to notify potential customers or contributors in advance of any data being collected. Others require that subjects be informed of how their data will be used, who will have access to it, and how to have it deleted if desired. Some methods of data collection are legislative, such as a government requirement that citizens obtain a registration number and that they use that number while interacting with government agencies, law enforcement, emergency services, and others. While some data collection techniques are striving to be more transparent, other techniques are nearly invisible. Simply browsing a website can generate scores of data points that can be used to influence what advertisements you see, what sorts of movies or books are offered, what medical offers or loan offers you receive. All of this data generates challenges for those trying to make use of it and those trying to control it. Both now and in the future, the rapid processing of large amounts of data will remain critical.

### SUMMARY

Datasets of great dimensions are processed in support of the goals, objectives, and missions of organizations large and small. The datasets are processed by submitting “processing jobs”, where the processing jobs access data, manipulate the data, store the data, and so on. The processing jobs that are performed are critical to the missions of the organizations. Typical processing jobs include generating invoices for accounts receivable, processing payments for accounts payable, running payroll, analyzing research data, or training a neural network for machine learning. These jobs are highly complex and involve many data handling tasks. The tasks can include loading and storing various datasets, accessing processing components and systems, executing data processing, and so on. The tasks themselves are based on multiple steps or subtasks which themselves can be complex. The subtasks can be used to handle specific jobs such as loading or reading data from storage, performing computations and other data manipulations, storing or writing the data back to storage, handling inter-subtask communication such as data transfer and control, and so on. The datasets that are accessed are vast and can easily overwhelm processing architectures that are either ill suited to the processing tasks or based on inflexible designs. Instead, two-dimensional (2D) arrays of elements can be used for the processing of the tasks and subtasks, thereby significantly improving task processing efficiency and throughput. The 2D arrays include compute elements, multiplier elements, registers, caches, queues, controllers, decompressors, arithmetic logic units (ALUs), storage elements, and other components which can communicate among themselves.

The 2D array of elements is configured and operated by providing control to the array of elements on a cycle-by-cycle basis. The control of the 2D array is accomplished by providing control words generated by a compiler. The control includes a stream of control words, where the control words can include variable length control words generated by the compiler. The control words are used to configure the array, to control the flow or transfer of data, and to manage the processing of the tasks and subtasks. Further, the arrays can be configured in a topology which is best suited to the task processing. The topologies into which the arrays can be configured include a systolic, a vector, a cyclic, a spatial, a streaming, or a Very Long Instruction Word (VLIW) topology, among others. The topologies can include a topology that enables machine learning functionality. The control words can be compressed to reduce storage requirements for the control words. Further, the compressed control words can be “bin packed” into frames, where the frames include a number of bytes such as 512 bits. The bin packing enables one or more compressed control words to be loaded into a frame. The compiler enables linking of the compressed control words by providing linking information in at least one field of each compressed control word. The linking information enables the compressed control words to be ordered into an operationally sequenced order prior to decompressing the compressed control words and executing compute element operations associated with the control words.

Parallel processing is based on a parallel processing architecture with bin packing. A two-dimensional (2D) array of compute elements is accessed, wherein each compute element within the array of compute elements is known to a compiler and is coupled to its neighboring compute elements within the array of compute elements. A plurality of compressed control words is generated by the compiler, wherein the plurality of control words enables compute element operation and compute element memory access, and wherein the plurality of compressed control words is operationally sequenced. The plurality of compressed control words is linked by the compiler, wherein linking information is contained in at least one field of each of the plurality of compressed control words. The plurality of compressed control words is loaded into a control word cache coupled to the array of compute elements, wherein the plurality of compressed control words is loaded into the control word cache in an operationally non-sequenced order. The plurality of compressed control words is ordered into an operationally sequenced execution order, based on the linking information.

A processor-implemented method for parallel processing is disclosed comprising: accessing an array of compute elements, wherein each compute element within the array of compute elements is known to a compiler and is coupled to its neighboring compute elements within the array of compute elements; generating a plurality of compressed control words by the compiler, wherein the plurality of control words enables compute element operation and compute element memory access, and wherein the plurality of compressed control words is operationally sequenced; linking the plurality of compressed control words, by the compiler, wherein linking information is contained in at least one field of each of the plurality of compressed control words; loading the plurality of compressed control words into a control word cache coupled to the array of compute elements, wherein the plurality of compressed control words is loaded into the control word cache in an operationally non-sequenced order; and ordering the plurality of compressed control words into an operationally sequenced execution order, based on the linking information. Some embodiments comprise decompressing the plurality of compressed control words. Some embodiments comprise executing operations within the array of compute elements, using the plurality of compressed control words that were decompressed. In embodiments, the decompressing operates on compressed control words that were ordered before they are presented to the array of compute elements. And some embodiments comprise aligning the plurality of compressed control words.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a parallel processing architecture with bin packing.

FIG. 2 is a flow diagram for compressed control word (CCW) decompression.

FIG. 3 is a high-level block diagram showing bin packed compressed control words.

FIG. 4 is a system block diagram for a highly parallel architecture with a shallow pipeline.

FIG. 5 shows compute element array detail.

FIG. 6 is a system block diagram for compiler interactions.

FIG. 7 is a system block diagram for a compute element.

FIG. 8 is a system diagram for a parallel processing architecture with bin packing.

### DETAILED DESCRIPTION

Techniques for a parallel processing architecture with bin packing are disclosed. Compressed control words that are generated by a compiler are “bin packed” into frames. The frames, which can be associated with storage such as a control word cache associated with a 2D array of compute elements, comprise a number of bytes such as 512 bytes. The compressed control words can include variable length control words. The variable length compressed control words are loaded into the frames by bin packing the compressed control words into the frames. The bin packing maximizes a number of compressed control words that are contained within a frame while minimizing the number of frames required to store the compressed control words. The bin packing loads the compressed control words in an operationally non-sequenced order. The compiler links the compressed control words at the time of generation by providing linking information within at least one field of each of the compressed control words. The linking information is used to describe an order of execution of the compressed control words. The bin packed compressed control words are ordered into an operationally sequenced execution order based on the linking information. The ordered compressed control words are decompressed, and compute element operations associated with the compressed control words that were decompressed are executed.

In order for tasks, subtasks, and so on to execute properly, particularly in a statically scheduled architecture such as a two-dimensional (2D) array of compute elements, one or more operations associated with one or more control words must be executed in an operationally sequenced order. One technique for loading the compressed control words into storage such as a control word cache coupled to the 2D array of compute elements would be to load one compressed control word per frame in the operationally sequenced order of the compressed control words. However, since the compressed control words can comprise varying length control words, substantial fragmentation of the storage would result. In this context, fragmentation refers to unused storage within a unit of storage such as a frame. Rather than using such a wasteful storage technique, the compressed control words can be bin packed into frames associated with the control word cache. The bin packing of the compressed control words loads the compressed control words into frames based on a “where they fit” (e.g., bin packing) technique rather than loading the compressed control words into frames in their operationally sequenced order. This bin packing technique significantly reduces storage fragmentation and lowers the number of frames required to store the compressed control words. The out-of-order or operationally non-sequenced order of compressed control words in the bin packed frames can be ordered into an operationally sequenced execution order by accessing frames, aligning compressed control words within the frames with a frame edge, decompressing the compressed control words, and executing operations associated with the compressed control words that were decompressed. The ordering of the compressed control words is based on the linking information provided by the compiler. The aligning is accomplished by shifting the compressed control words to align with a frame edge. Execution of the operations is further based on processing compute element memory access requests and providing requested data when and where the data is required for processing. The processing is based on data manipulation.

The data manipulations are performed on a two-dimensional (2D) array of compute elements. The compute elements within the 2D array can be implemented with central processing units (CPUs), graphics processing units (GPUs), application specific integrated circuits (ASICs), field programmable gate arrays (FPGAs), processing cores, or other processing components or combinations of processing components. The compute elements can include heterogeneous processors, homogeneous processors, processor cores within an integrated circuit or chip, etc. The compute elements can be coupled to local storage which can include local memory elements, register files, cache storage, etc. The cache, which can include a hierarchical cache, such as a level 1 (L1), a level 2 (L2), and a level 3 (L3) cache working together, can be used for storing data such as intermediate results, compressed control words, coalesced control words, decompressed control words, relevant portions of a control word, and the like. The cache can store data produced by a taken branch path, where the taken branch path is determined by a branch decision. The decompressed control word is used to control one or more compute elements within the array of compute elements. Multiple layers of the two-dimensional (2D) array of compute elements can be “stacked” to comprise a three-dimensional array of compute elements.

The tasks, subtasks, etc., that are associated with processing operations are generated by a compiler. The compiler can include a general-purpose compiler, a hardware description-based compiler, a compiler written or “tuned” for the array of compute elements, a constraint-based compiler, a satisfiability-based compiler (SAT solver), and so on. Control is provided to the hardware in the form of control words, where one or more control words are generated by the compiler. The control words are provided to the array on a cycle-by-cycle basis. The control words can include wide microcode control words. The length of a microcode control word can be adjusted by compressing the control word. The compressing can be accomplished by recognizing situations where a compute element is unneeded by a task. Thus, control bits within the control word associated with the unneeded compute elements are not required for that compute element. Other compression techniques can also be applied. The control words can be used to route data, to set up operations to be performed by the compute elements, to idle individual compute elements or rows and/or columns of compute elements, etc. The compiled microcode control words associated with the compute elements are distributed to the compute elements. The compute elements are controlled by a control unit which decompresses the control words. The decompressed control words enable processing by the compute elements. The task processing is enabled by executing the one or more control words. In order to accelerate the execution of tasks, to reduce or eliminate stalling for the array of compute elements, and so on, copies of data can be broadcast to a plurality of physical register files comprising 2R1 W memory elements. The register files can be distributed across the 2D array of compute elements.

A parallel processing architecture with bin packing enables task processing. The task processing can include data manipulation. A two-dimensional (2D) array of compute elements is accessed, wherein each compute element within the array of compute elements is known to a compiler and is coupled to its neighboring compute elements within the array of compute elements. The compute elements can include compute elements, processors, or cores within an integrated circuit; processors or cores within an application specific integrated circuit (ASIC); cores programmed within a programmable device such as a field programmable gate array (FPGA); and so on. The compute elements can include homogeneous or heterogeneous processors. Each compute element within the 2D array of compute elements is known to a compiler. The compiler, which can include a general-purpose compiler, a hardware-oriented compiler, or a compiler specific to the compute elements, can compile code for each of the compute elements. Each compute element is coupled to its neighboring compute elements within the array of compute elements. The coupling of the compute elements enables data communication between and among compute elements. Thus, the compiler can control data flow between and among the compute elements and can also control data commitment to memory outside of the array.

A plurality of compressed control words is generated by the compiler, wherein the plurality of control words enables compute element operation and compute element memory access, and wherein the plurality of compressed control words is operationally sequenced. The operational sequence indicates an order of execution for the compressed control words. The compressed control words can control the array of compute elements on a cycle-by-cycle basis. A cycle can include a clock cycle, an architectural cycle, a system cycle, etc. The stream of wide control words generated by the compiler provides direct, fine-grained control of the 2D array of compute elements. The fine-grained control can include control of individual compute elements, memory elements, control elements, etc. The plurality of compressed control words is linked by the compiler, wherein linking information is contained in at least one field of each of the plurality of compressed control words. The linking information can include an address, a relative address, an offset, or a pointer. The pointer can be associated with a linked list, where the linked list represents the operationally sequenced execution order of the control words, and the pointer points to the next control word. The plurality of compressed control words is loaded into a control word cache coupled to the array of compute elements, wherein the plurality of compressed control words is loaded into the control word cache in an operationally non-sequenced order. The operationally non-sequenced order can be based on a “best fit” or bin packed technique. The plurality of compressed control words is ordered into an operationally sequenced execution order, based on the linking information. The ordering can include shifting one or more compressed control words to align the compressed control words. The ordered compressed control words are decompressed, and operations associated with the compressed control words that were decompressed are executed.

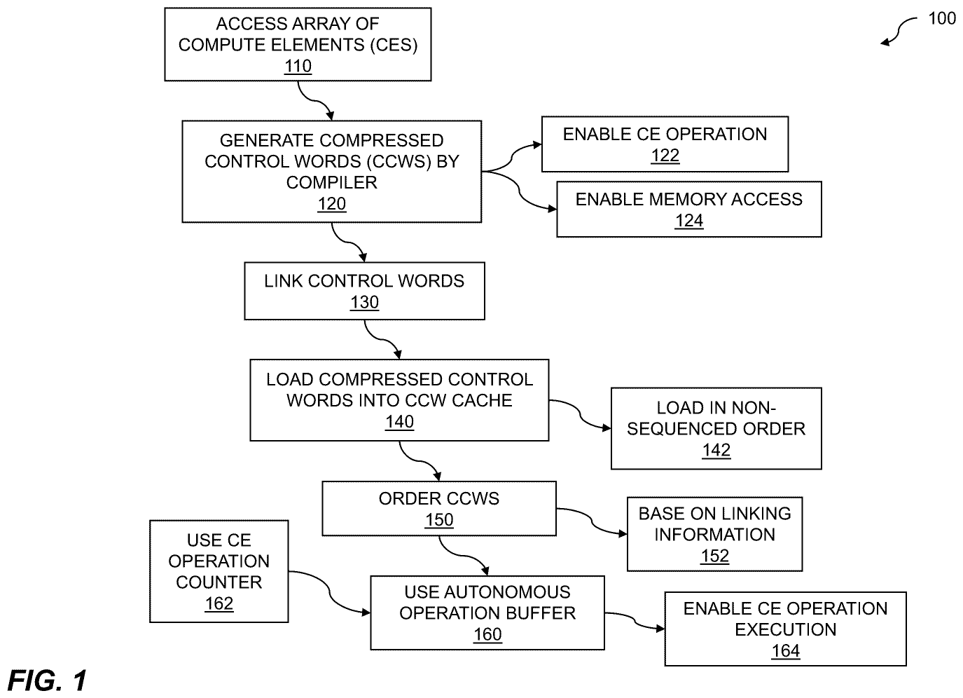

FIG. 1 is a flow diagram for a parallel processing architecture with bin packing. Groupings of compute elements (CEs), such as CEs assembled within a 2D array of CEs, can be configured to execute a variety of operations associated with data processing. The operations can be based on tasks, and on subtasks that are associated with the tasks. The 2D array can further interface with other elements such as controllers, storage elements, ALUs, memory management units (MMUs), GPUs, multiplier elements, and so on. The operations can accomplish a variety of processing objectives such as application processing, data manipulation, data analysis, and so on. The operations can manipulate a variety of data types including integer, real, floating-point, and character data types; vectors and matrices; tensors; etc. Control is provided to the array of compute elements on a cycle-by-cycle basis, where the control is based on control words generated by a compiler. The control words, which can include microcode control words, enable or idle various compute elements; provide data; route results between or among CEs, caches, and storage; and the like. The control enables compute element operation, memory access precedence, etc. Compute element operation and memory access precedence enable the hardware to properly sequence data provision and compute element results. The control enables execution of a compiled program on the array of compute elements.

The flow 100 includes accessing an array 110 of compute elements, wherein each compute element within the array of compute elements is known to a compiler and is coupled to its neighboring compute elements within the array of compute elements. The compute elements can be based on a variety of types of processors. The compute elements or CEs can include central processing units (CPUs), graphics processing units (GPUs), processors or processing cores within application specific integrated circuits (ASICs), processing cores programmed within field programmable gate arrays (FPGAs), and so on. In embodiments, compute elements within the array of compute elements have identical functionality. The compute elements can include heterogeneous compute resources, where the heterogeneous compute resources may or may not be colocated within a single integrated circuit or chip. The compute elements can be configured in a topology, where the topology can be built into the array, programmed or configured within the array, etc. In embodiments, the array of compute elements is configured by a control word that can implement a topology. The topology that can be implemented can include one or more of a systolic, a vector, a cyclic, a spatial, a streaming, or a Very Long Instruction Word (VLIW) topology. In embodiments, the array of compute elements can include a two-dimensional (2D) array of compute elements. More than one 2D array of compute elements can be accessed. Two or more 2D arrays of compute elements can be colocated on an integrated circuit or chip, on multiple chips, and the like. In embodiments, the two-dimensional array of compute elements can be stacked to form a three-dimensional array. The stacking of the 2D arrays of compute elements can be accomplished using a variety of techniques. In embodiments, the three-dimensional (3D) array can be physically stacked. The 3D array can comprise a 3D integrated circuit. In other embodiments, the three-dimensional array is logically stacked. The logical stacking can include configuring two or more 2D arrays of compute elements to operate as if they were physically stacked.

The compute elements can further include a topology suited to machine learning computation. A topology for machine learning can include supervised learning, unsupervised learning, reinforcement learning, and other machine learning topologies. The compute elements can be coupled to other elements within the array of CEs. In embodiments, the coupling of the compute elements can enable one or more further topologies. The other elements to which the CEs can be coupled can include storage elements such as one or more levels of cache storage; control units; multiplier units; address generator units for generating load (LD) and store (ST) addresses; queues; register files; and so on. The compiler to which each compute element is known can include a C, C++, or Python compiler. The compiler to which each compute element is known can include a compiler written especially for the array of compute elements. The coupling of each CE to its neighboring CEs enables clustering of compute resources; sharing of elements such as cache elements, multiplier elements, ALU elements, or control elements; communication between or among neighboring CEs; and the like.

The flow 100 includes generating 120 a plurality of compressed control words by the compiler, wherein the plurality of compressed control words is operationally sequenced. Data processing that can be performed by the 2D array of compute elements can be accomplished by executing tasks, subtasks, and so on. The tasks and subtasks can be represented by control words, where the control words configure and control compute elements within the 2D array of compute elements. The control words comprise one or more operations, where the operations can include data load and store operations; data manipulation operations such as arithmetic, logical, matrix, and tensor operations; and so on. The control words can be compressed by the compiler, by a compressor, and the like. In the flow 100, the plurality of control words enables compute element operation 122. The compute element operations can include arithmetic operations such as addition, subtraction, multiplication, and division; logical operations such as AND, OR, NAND, NOR, XOR, XNOR, and NOT; matrix operations such as dot product and cross product operations; tensor operations such as tensor product, inner tensor product, and outer tensor product; etc. The control words can comprise one or more fields. The fields can include one or more of an operation, a tag, data, and so on. In embodiments, a field of a control word in the plurality of control words can signify a “repeat last operation” control word. The repeat last operation control word can include a number of operations to repeat, a number of times to repeat the operations, etc. In the flow 100, the plurality of control words enables compute element memory access 124. Memory access can include access to local storage or memory coupled to a compute element, storage shared by two or more compute elements, cache memory such as level 1 (L1), level 2 (L2), and level 3 (L3) cache memory, a memory system, etc. The memory access can include loading data, storing data, and the like.

In embodiments, the array of compute elements can be controlled on a cycle-by-cycle basis. The controlling the array can include configuration of elements such as compute elements within the array; loading and storing data; routing data to, from, and among compute elements; and so on. A cycle can include a clock cycle, an architectural cycle, a system cycle, a self-timed cycle, and the like. In embodiments, the plurality of compressed control words can include variable length control words. The compressed control words can further include wide compressed control words. The compressed control words can be provided as a stream. The control words can include microcode control words, compressed control words, encoded control words, and the like. The “wideness” of the control words allows a plurality of compute elements within the array of compute elements to be controlled by a single wide control word. For example, an entire row of compute elements can be controlled by that wide control word. The control words can be decompressed, used, etc., to configure the compute elements and other elements within the array; to enable or disable individual compute elements, rows and/or columns of compute elements; to load and store data; to route data to, from, and among compute elements; and so on.

Various types of compilers can be used to generate the plurality of compressed control words. The compiler which generates the compressed control words can include a general-purpose compiler such as a C, C++, or Python compiler; a hardware description language compiler such as a VHDL or Verilog compiler; a compiler written for the array of compute elements; and the like. In embodiments, the compressed control words comprise variable length control words. In embodiments, the plurality of compressed control words generated by the compiler can provide direct fine-grained control of the 2D array of compute elements. The compiler can be used to map functionality to the array of compute elements. In embodiments, the compiler can map machine learning functionality to the array of compute elements. The machine learning can be based on a machine learning (ML) network, a deep learning (DL) network, a support vector machine (SVM), etc. In embodiments, the machine learning functionality can include a neural network (NN) implementation. The neural network implementation can include a plurality of layers, where the layers can include one or more of input layers, hidden layers, output layers, and the like. A control word generated by the compiler can be used to configure one or more CEs, to enable data to flow to or from the CE, to configure the CE to perform an operation, and so on. Depending on the type and size of a task that is compiled to control the array of compute elements, one or more of the CEs can be controlled, while other CEs are unneeded by the particular task. A CE that is unneeded can be marked in the control word as unneeded. An unneeded CE requires no data and no control word. In embodiments, the unneeded compute element can be controlled by a single bit. In other embodiments, a single bit can control an entire row of CEs by instructing hardware to generate idle signals for each CE in the row. The single bit can be set for “unneeded”, reset for “needed”, or set for a similar usage of the bit to indicate when a particular CE is unneeded by a task.

The plurality of compressed control words that is generated by the compiler can include a conditionality such as a branch. The branch can include a conditional branch, an unconditional branch, etc. The compressed control words can be a decompressed by a decompressor logic block that decompresses words from a compressed control word cache on their way to the array. In embodiments, a set of operations associated with one or more compressed control words can include a spatial allocation of subtasks on one or more compute elements within the array of compute elements. In other embodiments, the set of operations can enable multiple, simultaneous programming loop instances circulating within the array of compute elements. The multiple programming loop instances can include multiple instances of the same programming loop, multiple programming loops, etc.

The flow 100 includes linking 130 the plurality of compressed control words, by the compiler, wherein linking information is contained in at least one field of each of the plurality of compressed control words. The linking can be used to indicate an operationally sequenced order in which one or more operations associated with one or more compressed control words are to be executed (discussed below). The linking can be accomplished using a variety of techniques. In embodiments, the linking information can include an address for the next compressed control word, a relative address, an offset, a pointer, and so on. The linking information can be based on a linked list in which the linking information enables access to or “points to” the next element of the linked list, where the next element comprises a compressed control word.

The flow 100 includes loading 140 the plurality of compressed control words into a control word cache coupled to the array of compute elements. More than one control word cache can be coupled to the array of compute elements. The control word cache can include a fast local memory that can be used to hold compressed control words such as variable length compressed control words prior to decompression and subsequent execution by one or more compute elements within the array of compute elements. In embodiments, the plurality of compressed control words is loaded into the control word cache using a fixed frame format. The fixed frame format can include a number of bytes, words, etc. In embodiments, the fixed frame format comprises 512 bytes. The fixed frame format can be larger than the length of a variable length compressed control word. In embodiments, the fixed frame format encompasses the plurality of compressed control words. That is, the longest variable length compressed control word can fit within the fixed frame format. In other embodiments, the fixed frame format can include unused space between at least two of the plurality of compressed control words. Storing a single compressed control word into the larger fixed frame format causes fragmentation of the control word cache. When unused storage space remains within a fixed frame after loading a compressed control word into the frame, then one or more additional compressed control words may “fit” into the remaining storage space. The fitting additional compressed control words into the unused space associated with a fixed frame can be accomplished using a bin packing technique. A bin packing technique is based on the classic optimization problem of packing objects of different sizes into a finite number of containers or bins. Here, the optimization problem is to load the plurality of variable length compressed control words into a minimum number of fixed format frames. In embodiments, the linking information enables bin packing in the control word cache. In the flow 100, the plurality of compressed control words is loaded 142 into the control word cache in an operationally non-sequenced order. The operationally non-sequenced order results from packing the compressed control words essentially wherever the compressed control words fit into the fixed frames. As a result, the loading can be performed without regard to the operationally sequenced order since the order can be reestablished based on the linking information.

The flow 100 includes ordering 150 the plurality of compressed control words into an operationally sequenced execution order. The bin packed compressed control words can be ordered by examining the one or more compressed control words within a given frame. In embodiments, the ordering can be performed on the plurality of compressed control words that were loaded from control word cache. In the flow 100, the ordering is based on the linking information 152. Even though the compressed control words were loaded into the control word cache using a bin packing technique, the linking information provides an order of execution for the compressed control words, thereby enabling the ordering. Note that the first compressed control word within the fixed frame format can be aligned with a frame edge. The alignment with the frame edge enables proper decompressing of the compressed control word and subsequent execution of one or more operations associated with the compressed control word. However, any remaining compressed control words within a fixed frame are not aligned with a frame edge. Further embodiments include aligning the plurality of compressed control words. The aligning can include aligning the compressed control words with a fixed frame edge. In embodiments, the aligning can include aligning with the left edge of the fixed frame. Various techniques can be used for the aligning. In embodiments, the aligning is accomplished using a shift register. If the aligning is always positioned on the left edge of the fixed frame, then a simplified shift register that shifts only left can be used. Note that the first compressed control word within a fixed frame is loaded and aligned with the frame edge. Embodiments further include bypassing the shift register for a compressed control word that is already aligned. The bypassing the shift register can be accomplished using a “zero shift” operation, a bypass data path that skirts the shift register, etc.

Further embodiments include decompressing the plurality of compressed control words. The ordered, compressed control words that were stored within the control word cache can be decompressed. The decompressed control words can comprise one or more operations, where the operations can be executed by one or more compute elements within the array of compute elements. The decompressing the compressed control words can be accomplished using a decompressor element. The decompressor element can be coupled to the array of compute elements. In embodiments, the decompressing by a decompressor operates on compressed control words that were ordered before they are presented to the array of compute elements. The presented compressed control words that were decompressed can be executed by one or more compute elements. Further embodiments include executing operations within the array of compute elements using the plurality of compressed control words that were decompressed. The executing operations can include configuring compute elements, loading data, processing data, storing data, generating control signals, and so on. The executing the operations within the array can be accomplished using a variety of processing techniques such as sequential execution techniques, parallel processing techniques, etc.

The control words that are generated by the compiler can include a conditionality. In embodiments, the control includes a branch. Code, which can include code associated with an application such as image processing, audio processing, and so on, can include conditions which can cause execution of a sequence of code to transfer to a different sequence of code. The conditionality can be based on evaluating an expression such as a Boolean or arithmetic expression. In embodiments, the conditionality can determine code jumps. The code jumps can include conditional jumps as just described, or unconditional jumps such as a jump to halt, exit, or terminate an operation. The conditionality can be determined within the array of elements. In embodiments, the conditionality can be established by a control unit. In order to establish conditionality by the control unit, the control unit can operate on a control word provided to the control unit. In embodiments, the control unit can operate on decompressed control words. The control words can be a decompressed by a decompressor logic block that decompresses words from a compressed control word cache on their way to the array. In embodiments, the set of directions can include a spatial allocation of subtasks on one or more compute elements within the array of compute elements.

The operations that are performed by the compute elements within the array can include arithmetic operations, logical operations, matrix operations, tensor operations, and so on. The operations that are executed are contained in the control words. Discussed above, the control words can include a stream of wide, variable length, control words generated by the compiler. The control words can be used to control the array of compute elements on a cycle-by-cycle basis. A cycle can include a local clock cycle, a self-timed cycle, a system cycle, and the like. In embodiments, the executing occurs on an architectural cycle basis. An architectural cycle can include a read-modify-write cycle. In embodiments, the architectural cycle basis reflects non-wall clock, compiler time. The execution can include distributed execution of operations. In embodiments, the distributed execution of operations can occur in two or more compute elements within the array of compute elements, within a grouping of compute elements, and so on. The compute elements can include independent compute elements, clustered compute elements, etc. Execution of specific compute element operations can enable parallel operation processing. The parallel operation processing can include processing nodes of a graph that are independent of each other, processing independent tasks and subtasks, etc. The operations can include arithmetic, logic, array, matrix, tensor, and other operations. A given compute element can be enabled for operation execution, idled for a number of cycles when the compute element is not needed, etc. The operations that are executed can be repeated. An operation can be based on a plurality of control words.

The operation that is being executed can include data dependent operations. In embodiments, the plurality of control words includes two or more data dependent branch operations. The branch operation can include two or more branches where a branch is selected based on an operation such as an arithmetic or logical operation. In a usage example, a branch operation can determine the outcome of an expression such as A>B. If A is greater than B, then one branch can be taken. If A is less than or equal to B, then another branch can be taken. In order to expedite execution of a branch operation, sides of the branch can be precomputed prior to datum A and datum B being available. When the data is available, the expression can be computed, and the proper branch direction can be chosen. The untaken branch data and operations can be discarded, flushed, etc. In embodiments, the two or more data dependent branch operations can require a balanced number of execution cycles. The balanced number of execution cycles can reduce or eliminate idle cycles, stalling, and the like. In embodiments, the balanced number of execution cycles is determined by the compiler. In embodiments, the generating, the customizing, and the executing can enable background memory access. The background memory access can enable a control element to access memory independently of other compute elements, a controller, etc. In embodiments, the background memory access can reduce load latency. Load latency is reduced since a compute element can access memory before the compute element exhausts the data that the compute element is processing.

The flow 100 further includes using an autonomous operation buffer 160 in at least one of the compute elements of the array of compute elements. The autonomous operation buffer can be loaded with an operation that can be executed using a “fire and forget” technique, where operations are loaded in the autonomous operation buffer and the operations can be executed without further supervision by a control word. The autonomous operation of the compute element can be based on operational looping, where the operational looping is enabled without additional control word loading. The looping can be enabled based on ordering memory access operations such that memory access hazards are avoided. Note that latency associated with access by a compute element to storage can be significant and can cause operation of the compute element to stall. The flow 100 further includes using a compute element operation counter 162 coupled to the autonomous operation buffer. The compute element operation counter can be used to control a number of times that the operations within the autonomous operation buffer are cycled through. The compute element operation counter can be used to indicate or “point to” the next operation to be provided to a compute element, a multiplier element, and ALU, or another element within the array of compute elements. In the flow 100, the autonomous operation buffer and the compute element operation counter enable 164 compute element operation execution. The compute element operation execution can include executing one or more operations, looping executions, and the like. In embodiments, the compute element operation execution involves operations not explicitly specified in a control word. Operations not explicitly specified in a control word can include low level operations with the array of compute elements such as data transfer protocols, execution completion and other signal generation techniques, etc.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

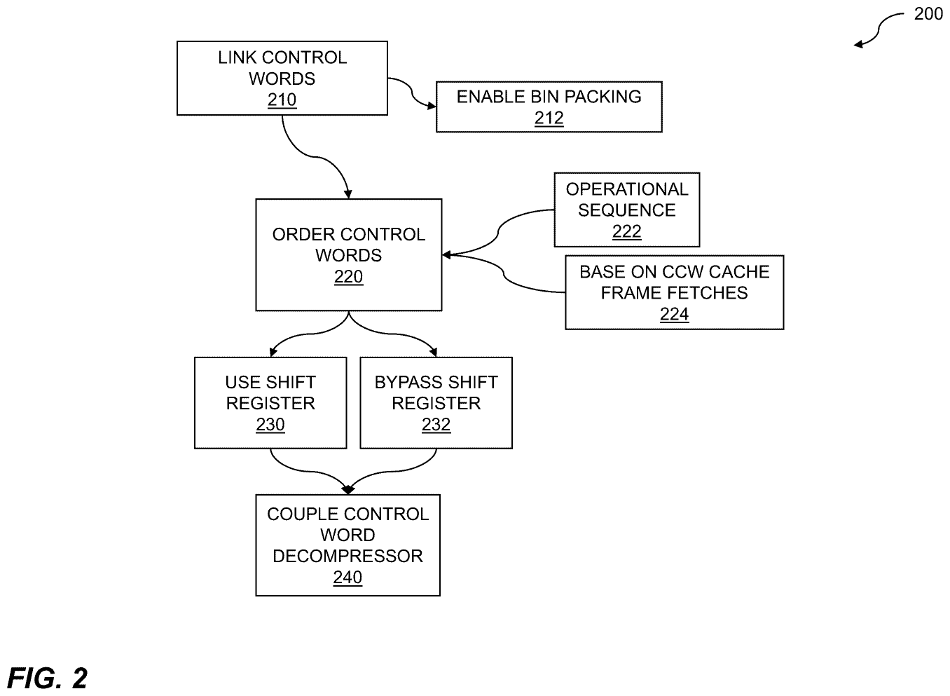

FIG. 2 is a flow diagram for compressed control word (CCW) decompression. A two-dimensional array of compute elements can be controlled using one or more control words. The control words can be generated by a compiler and can be used to configure one or more compute elements within the array to perform operations such as arithmetic, logical, matrix, or tensor operations; to enable memory access; and so on. The control words can include variable length control words. In order for the control words to be provided to and stored more efficiently in the 2D array, the control words can be compressed. The compressing of the control words can be accomplished by the compiler. The compressed control words can be stored more efficiently since the compressed words can be shorter than the decompressed control words. Further, the compressed control words can be bin packed. Just like the classic bin packing problem where different sized objects must be placed into containers or bins, compressed control words of varying sizes can be packed into fixed-sized frames. In embodiments, the frames can include 512 bytes each. The bin packed compressed control words can be stored in an operationally non-sequenced order, but can be stored using fewer frames. In order for the bin packed compressed control words to be executed, the compressed control words must be ordered in an operationally sequenced order and must be decompressed. The decompressed control words comprise one or more compute element operations. The compressed control words that were decompressed, and the compute element operations and memory accesses associated with the decompressed control words, can be executed. Compressed control word decompression enables a parallel processing architecture using bin packing. An array of compute elements is accessed, wherein each compute element within the array of compute elements is known to a compiler and is coupled to its neighboring compute elements within the array of compute elements. A plurality of compressed control words is generated by the compiler, wherein the plurality of control words enables compute element operation and compute element memory access, and wherein the plurality of compressed control words is operationally sequenced. The plurality of compressed control words is linked by the compiler, wherein linking information is contained in at least one field of each of the plurality of compressed control words. The plurality of compressed control words is loaded into a control word cache coupled to the array of compute elements, wherein the plurality of compressed control words is loaded into the control word cache in an operationally non-sequenced order. The plurality of compressed control words is ordered into an operationally sequenced execution order, based on the linking information.

The flow 200 includes linking 210 the plurality of compressed control words by the compiler. The linking can indicate an order of execution for one or more compressed control words. One or more operations can be associated with a compressed control word. The one or more compressed control words can be generated in an operationally sequenced order. In a usage example, the compiler can generate compressed control words in a sequenced order such as CCW0, CCW1, . . . CCWN. In embodiments, the linking information is contained in at least one field of each of the plurality of compressed control words. The linking information can include an address, a relative address, an offset, a pointer, and the like. In embodiments, the linking information can comprise a pointer associated with a linked list. Recall that the compressed control words generated by the compiler can include variable length compressed control words. The compressed control words can be loaded into frames, where the frames can include a number of bytes. In embodiments, a frame includes 512 bytes. Since a compressed control word can include linking information, the compressed control words do not necessarily have to be loaded into storage, such as a control word cache, in an operationally sequenced order. Instead, the compressed control words can be stored using a technique that minimizes a number of frames, amounts of storage, etc. required to store the compressed control words. In embodiments, the linking information enables bin packing 212 in the control word cache. The bin packing can include an optimization technique which can maximize a number of compressed control words that can be stored in a minimum number of frames. In embodiments, the compressed control words can be loaded into the control word cache coupled to the array of compute elements, wherein the plurality of compressed control words is loaded into the control word cache in an operationally non-sequenced order.

The flow 200 includes ordering 220 the plurality of compressed control words. Recall that the compressed control words can be loaded into a control word cache coupled to the array of compute elements, where the plurality of compressed control words can be loaded into the control word cache in an operationally non-sequenced order. The operationally non-sequential order can result from the bin packing technique used to store the compressed control words more efficiently. In the flow 200, the compressed control words are ordered into an operationally sequenced 222 execution order. In a usage example, a plurality of compressed control words can be stored in an operationally non-sequenced order such as CCW0, CCW1, CCW3, CCW5, CCW2, CCW7, CCW4, and CCW6. The compressed control words can be stored across a plurality of frames. Ordering the compressed control words into an operationally sequenced execution order can reorder the compressed control words into CCW0, CCW1, CCW2, CCW3, CCW4, CCW5, CCW6, and CCW7 order. In the flow 200, the ordering the plurality of compressed control words is based on frame fetches 224. Recall that a frame can include a number of bytes such as 512 bytes. The frame can be fetched from storage, where the storage can include the compressed control word cache.

One or more compressed control words can be stored in a given frame. The first compressed control word associated with the frame can be aligned with a frame edge such as the left frame edge. Any additional compressed control words may not be aligned with a frame edge. In order to align the additional compressed control words with a frame edge, the additional compressed control words can be shifted. Discussed below, additional compressed control words within a frame can be positioned to the right of the first compressed control word within the frame. In the flow 200, the aligning is accomplished using a shift register 230. Since any additional compressed control words within a frame can be positioned to the right of the first compressed control word within the frame, the shift can be accomplished using a simplified shift register, where the simplified shift register is only required to shift left. The shifting left can include shifting left by a number of bytes or other unit of storage. The flow 200 further includes bypassing the shift register 232 for a compressed control word that is already aligned. The bypassing the shift register can be accomplished by a “zero left” shift (e.g., no shift), by a pass-path within the shift register, by an alternate data path, etc.

The flow 200 includes coupling a decompressor 240. The decompressor can decompress the plurality of compressed control words. The compressed control words can include the compressed control words within the control word cache. The decompressor can be coupled to the 2D array of compute elements. In embodiments, the decompressor operates on compressed control words that were ordered before they are presented to the array of compute elements. The compressed control words that are decompressed can be used to configure one or more compute elements within the 2D array of compute elements. The configuring can include enabling or disabling a compute element, a row of compute elements, a column of compute elements, a region of the 2D array, and so on. The compressed control words that were decompressed can provide operations associated with parallel processing tasks, subtasks, and the like.

The control provided by the compressed control words that were decompressed can be provided on a cycle-by-cycle basis. In addition to configuring elements such as compute elements within the 2D array, the provided control can include loading and storing data; routing data to, from, and among compute elements; and so on. The control is enabled by a stream of variable length control words generated by the compiler. The control words can configure the compute elements and other elements within the array; enable or disable individual compute elements or rows and/or columns of compute elements; load and store data; route data to, from, and among compute elements; etc. The one or more control words are generated by the compiler as discussed above. The compiler can be used to map functionality to the array of compute elements. A control word generated by the compiler can be used to configure one or more CEs, to enable data to flow to or from the CE, to configure the CE to perform an operation, and so on. Depending on the type and size of a task that is compiled to control the array of compute elements, one or more of the CEs can be controlled, while other CEs are unneeded by the particular task. A CE that is unneeded can be marked in the control word as unneeded. An unneeded CE requires no data, nor is a control word portion, which can be called a control word bunch, required by it. In embodiments, the unneeded compute element can be controlled by a single bit. In other embodiments, a single bit can control an entire row of CEs by instructing hardware to generate idle signals for each CE in the row. The single bit can be set for “unneeded”, reset for “needed”, or set for a similar usage of the bit to indicate when a particular CE is unneeded by a task.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

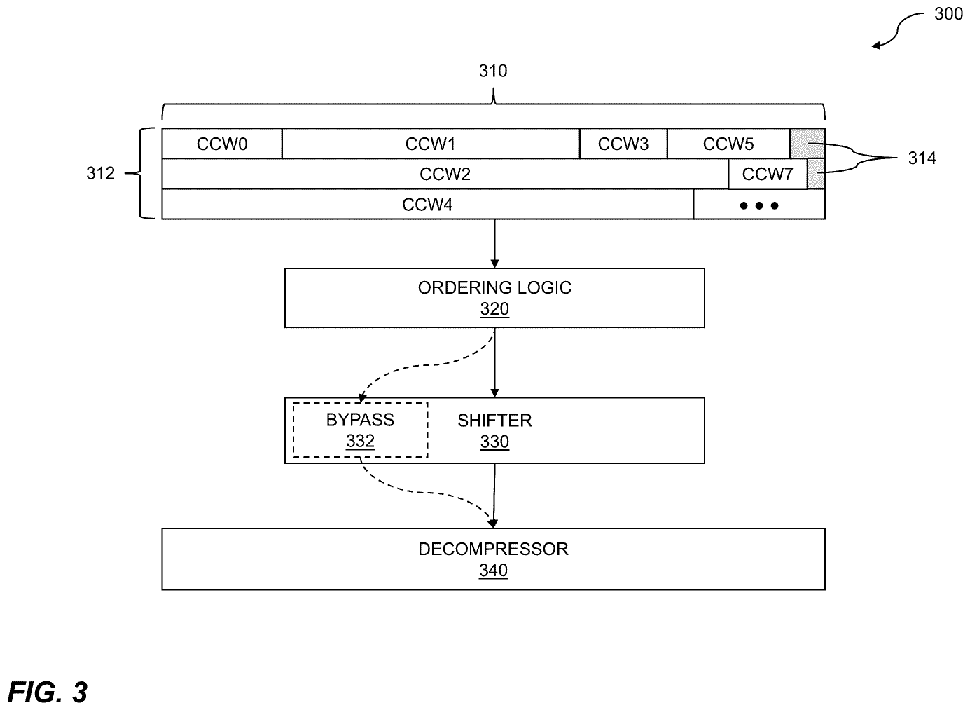

FIG. 3 is a high-level block diagram showing bin packed compressed control words. Discussed previously and throughout, compressed control words can be “bin packed” into storage such as cache storage. The bin packing can reduce the amount of storage required to store a plurality of compressed control words. Recall that the compressed control words can include variable length control words. However, because the amount of compression of each control word can vary based on the contents of the control word and the compression algorithm used, even fixed length control words, when compressed, can each require a different number of bytes for storage and transfer while in the compressed format. Instead of loading a single control word into a unit of storage, where the unit of storage can include a number of bytes, words, a block, a cache line, etc., compressed control words can be fitted, or bin packed, into the storage. Thus, two or more compressed control words can be loaded into a unit of storage, depending on the length of the variable length compressed control words. Note that the bin packing can cause the loading of the compressed control words into storage to be accomplished in a non-operationally sequenced order. In order for the non-operationally sequenced compressed control words to be accessed and decompressed prior to executing operations associated with the compressed control words, the compressed control words can be ordered. The ordering can be accomplished based on linking information provided by a compiler. The bin packed compressed control words enable a parallel processing architecture. An array of compute elements is accessed, wherein each compute element within the array of compute elements is known to a compiler and is coupled to its neighboring compute elements within the array of compute elements. A plurality of compressed control words is generated by the compiler, wherein the plurality of control words enables compute element operation and compute element memory access, and wherein the plurality of compressed control words is operationally sequenced. The plurality of compressed control words is linked by the compiler, wherein linking information is contained in at least one field of each of the plurality of compressed control words. The plurality of compressed control words is loaded into a control word cache coupled to the array of compute elements, wherein the plurality of compressed control words is loaded into the control word cache in an operationally non-sequenced order. The plurality of compressed control words is ordered into an operationally sequenced execution order, based on the linking information.

The high-level block diagram 300 includes a control word cache 310. The control word cache can be used to store a plurality of compressed control words, where the compressed control words can include variable length control words. In embodiments, the plurality of compressed control words can be loaded into the control word cache using a fixed frame format. The fixed frame format can include a number of bytes, words, and so on. In embodiments, the fixed frame format can include 512 bytes. The fixed frame format can be chosen to handle one or more variable length control words. In embodiments, the fixed frame format can encompass the plurality of compressed control words. That is, the longest length variable length compressed control word can be loaded into a single frame.

An example plurality of frames is shown 312. A frame can include one or more compressed control words. A first frame can include compressed control words CCW0, CCW1, CCW3, and CCW5. A second frame can include compressed control words CCW2 and CCW7. A third frame can include compressed control word CCW4. While three frames are shown, other numbers of frames can be used to store compressed control words associated with tasks, subtasks, processes, routines, and so on. Since the variable length compressed control words include different control word lengths, then a given frame may not be completely filled by the compressed control words loaded into it. In embodiments, the fixed frame format can include unused space between at least two of the plurality of compressed control words. The unused space comprises storage fragments 314 within a storage element such as the control word cache. Note also that the execution of operations associated with the compressed control words is based on an order of the control words. In a usage example, the compressed control words would be accessed in an order such as CCW0, CCW1, and so on through CCW7. Storage efficiency can be achieved by minimizing the amount of fragmentation based on unused space. In embodiments, the loading the plurality of compressed control words into a control word cache coupled to the array of compute elements is accomplished, wherein the plurality of compressed control words is loaded into the control word cache in an operationally non-sequenced order. To execute the compressed control words, the compressed control words can be ordered.

The high-level block diagram 300 includes ordering logic 320. The ordering logic can be used to orient or order the bin packed compressed control words which were loaded into the control word cache in an operationally non-sequenced order back into an operationally sequenced order. In embodiments, the ordering the plurality of compressed control words into an operationally sequenced execution order is accomplished based on linking information provided by the compiler. The ordering can be accomplished “on the fly” as compressed control words are obtained from the control word store by obtaining one or more frames. In embodiments, the ordering can be performed on the plurality of compressed control words that were loaded from control word cache.

The high-level block diagram 300 includes a shifter 330. The shifter can accomplish shifting of compressed control words that were loaded into a frame. Note that the first compressed control word illustrated within a frame is positioned to the left within the frame and that the subsequent compressed control words are positioned to the right. In order to position a compressed control word within a frame, contents of a frame can be shifted in order to align a compressed control word with a frame edge. This enables the compressed control words (CCWs) to be “left justified”, as it were, before their presentation to the decompressor (described below), so that all CCWs are presented to the decompressor in the same manner. Further embodiments can include aligning the plurality of compressed control words. The compressed control words can include the bin packed compressed control words within the control word cache. In embodiments, the aligning can be accomplished using a shift register. In the example 300, the shifter can be implemented using a simplified shifting technique where only left-shifting is required for alignment, without a need for right-shifting. In the figure, the compressed control words that can be shifted left can include CCW1, CCW3, CCW5, and CCW7. Note that other compressed control words that were loaded into the control word cache are already aligned at the left edge of their frames. These latter compressed control words include CCW0, CCW2, and CCW4. The latter compressed control words do not require shifting. Compressed control words that do not require shifting can bypass 332 the shifter. Further embodiments include bypassing the shift register for a compressed control word that is already aligned. The bypassing can be accomplished as a virtual bypass by performing a zero-shift operation, by traversing the shifter in an unshifted state, by bypassing the shifter, and so on.

The high-level block diagram 300 includes a decompressor 340. The decompressor can decompress one or more compressed control words. Further embodiments include decompressing the plurality of compressed control words. The compressed control words that can be decompressed can include the compressed control words that were loaded into the control word cache. In embodiments, the decompressor can operate on compressed control words that were ordered before they are presented to the array of compute elements. The decompressing can include extracting one or more compute element operations and compute element memory accesses associated with the compressed control words. The compute element operations can include arithmetic, logical, matrix, and tensor operations. The memory accesses can include access to one or more of a register file; local cache storage such as level 1 (L1), level 2 (L2), and level 3 (L3) cache storage; shared storage within the 2D array of compute elements; a memory system; and the like.

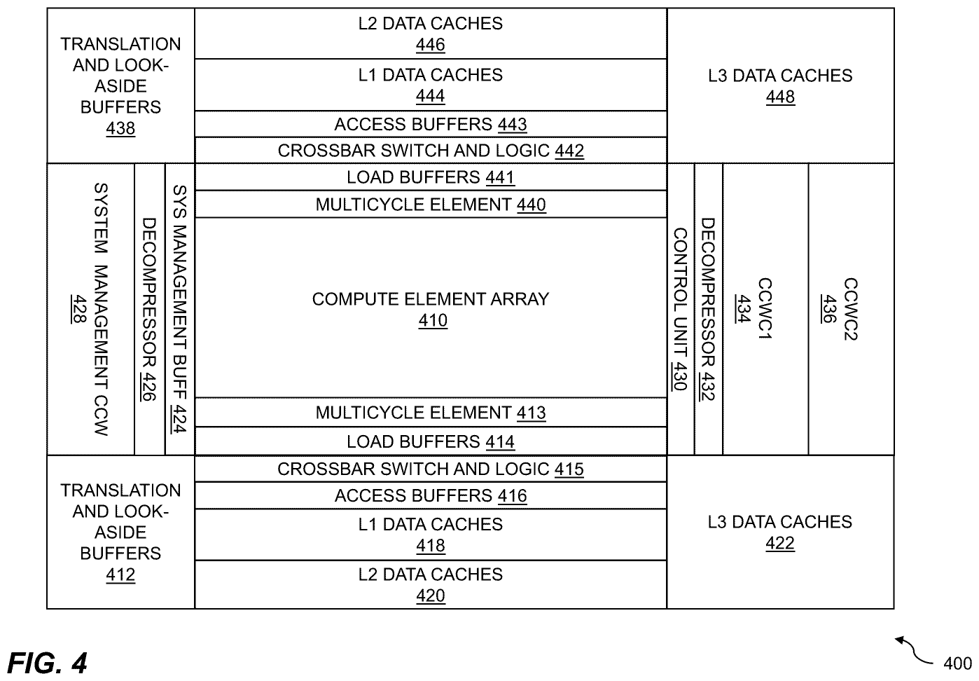

FIG. 4 is a system block diagram for a highly parallel architecture with a shallow pipeline. The highly parallel architecture can comprise a variety of components such as compute elements, processing elements, buffers, one or more levels of cache storage, system management, arithmetic logic units, multipliers, memory management units, and so on. The various components can be used to accomplish parallel processing of tasks, subtasks, and the like. The parallel processing is associated with program execution, job processing, etc. The parallel processing is enabled based on a parallel processing architecture with bin packing. A two-dimensional (2D) array of compute elements is accessed, wherein each compute element within the array of compute elements is known to a compiler and is coupled to its neighboring compute elements within the array of compute elements. A plurality of compressed control words is generated by the compiler, wherein the plurality of control words enables compute element operation and compute element memory access, and wherein the plurality of compressed control words is operationally sequenced. The plurality of compressed control words is linked by the compiler, wherein the linking information is contained in at least one field of each of the plurality of compressed control words. The plurality of compressed control words is loaded into a control word cache coupled to the array of compute elements, wherein the plurality of compressed control words is loaded into the control word cache in an operationally non-sequenced order. The plurality of compressed control words is ordered into an operationally sequenced execution order, based on the linking information.

A system block diagram 400 for a highly parallel architecture with a shallow pipeline is shown. The system block diagram can include a compute element array 410. The compute element array 410 can be based on compute elements, where the compute elements can include processors, central processing units (CPUs), graphics processing units (GPUs), coprocessors, and so on. The compute elements can be based on processing cores configured within chips such as application specific integrated circuits (ASICs), processing cores programmed into programmable chips such as field programmable gate arrays (FPGAs), and so on. The compute elements can comprise a homogeneous array of compute elements. The system block diagram 400 can include translation and look-aside buffers such as translation and look-aside buffers 412 and 438. The translation and look-aside buffers can comprise memory caches, where the memory caches can be used to reduce storage access times.

The system block diagram 400 can include logic for load and store access order and selection. The logic for load and store access order and selection can include crossbar switch and logic 415 along with crossbar switch and logic 442. Crossbar switch and logic 415 can accomplish load and store access order and selection for the lower data cache blocks (418 and 420), and crossbar switch and logic 442 can accomplish load and store access order and selection for the upper data cache blocks (444 and 446). Crossbar switch and logic 415 enables high-speed data communication between the lower-half compute elements of compute element array 410 and data caches 418 and 420 using access buffers 416. Crossbar switch and logic 442 enables high-speed data communication between the upper-half compute elements of compute element array 410 and data caches 444 and 446 using access buffers 443. The access buffers 416 and 443 allow logic 415 and logic 442, respectively, to hold, load, or store data until any memory hazards are resolved. In addition, splitting the data cache between physically adjacent regions of the compute element array can enable the doubling of load access bandwidth, the reducing of interconnect complexity, and so on. While loads can be split, stores can be driven to both lower data caches 418 and 420 and upper data caches 444 and 446.

The system block diagram 400 can include lower load buffers 414 and upper load buffers 441. The load buffers can provide temporary storage for memory load data so that it is ready for low latency access by the compute element array 410. The system block diagram can include dual level 1 (L1) data caches, such as L1 data caches 418 and 444. The L1 data caches can be used to hold blocks of load and/or store data, such as data to be processed together, data to be processed sequentially, and so on. The L1 cache can include a small, fast memory that is quickly accessible by the compute elements and other components. The system block diagram can include level 2 (L2) data caches. The L2 caches can include L2 caches 420 and 446. The L2 caches can include larger, slower storage in comparison to the L1 caches. The L2 caches can store “next up” data, results such as intermediate results, and so on. The L1 and L2 caches can further be coupled to level 3 (L3) caches. The L3 caches can include L3 caches 422 and 448. The L3 caches can be larger than the L2 and L1 caches and can include slower storage. Accessing data from L3 caches is still faster than accessing main storage. In embodiments, the L1, L2, and L3 caches can include 4-way set associative caches.

The system block diagram 400 can include lower multicycle element 413 and upper multicycle element 440. The multicycle elements (MEMs) can provide efficient functionality for operations, such as multiplication operations, that span multiple cycles. The MEMs can provide further functionality for operations that can be of indeterminant cycle length, such as some division operations, square root operations, and the like. The MEMs can operate on data coming out of the compute element array and/or data moving into the compute element array. Multicycle element 413 can be coupled to the compute element array 410 and load buffers 414, and multicycle element 440 can be coupled to compute element array 410 and load buffers 441.

The system block diagram 400 can include a system management buffer 424. The system management buffer can be used to store system management codes or control words that can be used to control the array 410 of compute elements. The system management buffer can be employed for holding opcodes, codes, routines, functions, etc. which can be used for exception or error handling, management of the parallel architecture for processing tasks, and so on. The system management buffer can be coupled to a decompressor 426. The decompressor can be used to decompress system management compressed control words (CCWs) from system management compressed control word buffer 428 and can store the decompressed system management control words in the system management buffer 424. The compressed system management control words can require less storage than the decompressed control words. The system management CCW component 428 can also include a spill buffer. The spill buffer can comprise a large static random-access memory (SRAM), which can be used to provide rapid support of multiple nested levels of exceptions.

The compute elements within the array of compute elements can be controlled by a control unit such as control unit 430. While the compiler, through the control word, controls the individual elements, the control unit can pause the array to ensure that new control words are not driven into the array. The control unit can receive a decompressed control word from a decompressor 432 and can drive out the decompressed control word into the appropriate compute elements of compute element array 410. The decompressor can decompress a control word (discussed below) to enable or idle rows or columns of compute elements, to enable or idle individual compute elements, to transmit control words to individual compute elements, etc. The decompressor can be coupled to a compressed control word store such as compressed control word cache 1 (CCWC1) 434. CCWC1 can include a cache such as an L1 cache that includes one or more compressed control words. CCWC1 can be coupled to a further compressed control word store such as compressed control word cache 2 (CCWC2) 436. CCWC2 can be used as an L2 cache for compressed control words. CCWC2 can be larger and slower than CCWC1. In embodiments, CCWC1 and CCWC2 can include 4-way set associativity. In embodiments, the CCWC1 cache can contain decompressed control words, in which case it could be designated as DCWC1. In that case, decompressor 432 can be coupled between CCWC1 434 (now DCWC1) and CCWC2 436.

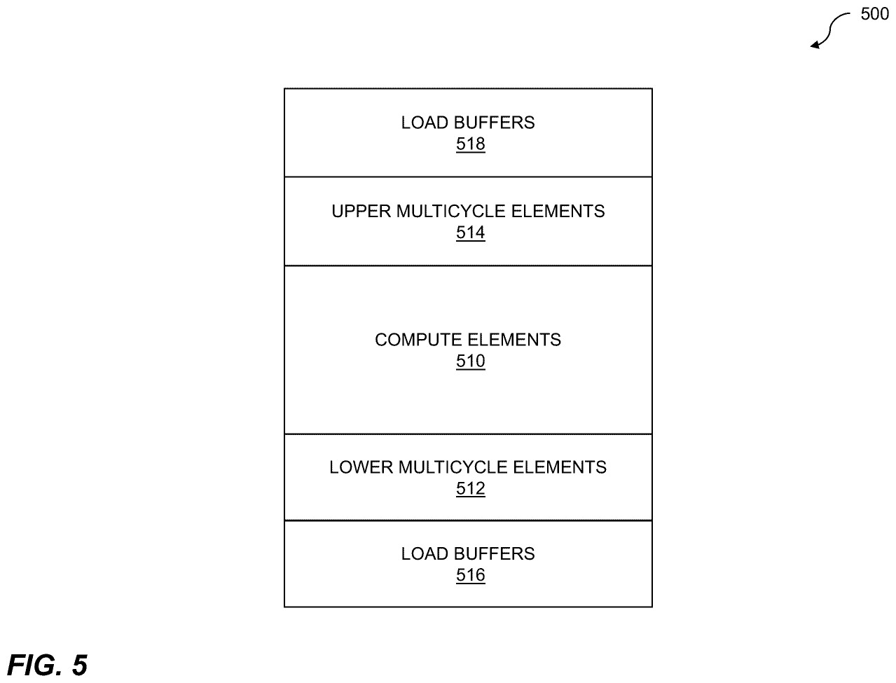

FIG. 5 shows compute element array detail 500. A compute element array can be coupled to components which enable the compute elements within the 2D array of compute elements to process one or more tasks, subtasks, and so on. The components can access and provide data, perform specific high-speed operations, and the like. The compute element array and its associated components enable a parallel processing architecture using bin packing. The compute element array 510 can perform a variety of processing tasks, where the processing tasks can include operations such as arithmetic, vector, matrix, or tensor operations; audio and video processing operations; neural network operations; etc. The compute elements can be coupled to multicycle elements such as lower multicycle elements 512 and upper multicycle elements 514. The multicycle elements can provide functionality to perform, for example, high-speed multiplications associated with general processing tasks, multiplications associated with neural networks such as deep learning networks, multiplications associated with vector operations, and the like. The multiplication operations can span multiple cycles. The MEMs can provide further functionality for operations that can be of indeterminant cycle length, such as some division operations, square root operations, and the like.

The compute elements can be coupled to load buffers such as load buffers 516 and load buffers 518. The load buffers can be coupled to the L1 data caches as discussed previously. In embodiments, a crossbar switch (not shown) can be coupled between the load buffers and the data caches. The load buffers can be used to load storage access requests from the compute elements. When an element is not explicitly controlled, it can be placed in the idle (or low power) state. No operation is performed, but ring buses can continue to operate in a “pass thru” mode to allow the rest of the array to operate properly. When a compute element is used just to route data unchanged through its ALU, it is still considered active.

While the array of compute elements is paused, background loading of the array from the memories (data memory and control word memory) can be performed. The memory systems can be free running and can continue to operate while the array is paused. Because multicycle latency can occur due to control signal transport that results in additional “dead time”, allowing the memory system to “reach into” the array and to deliver load data to appropriate scratchpad memories can be beneficial while the array is paused. This mechanism can operate such that the array state is known, as far as the compiler is concerned. When array operation resumes after a pause, new load data will have arrived at a scratchpad, as required for the compiler to maintain the statically scheduled model.

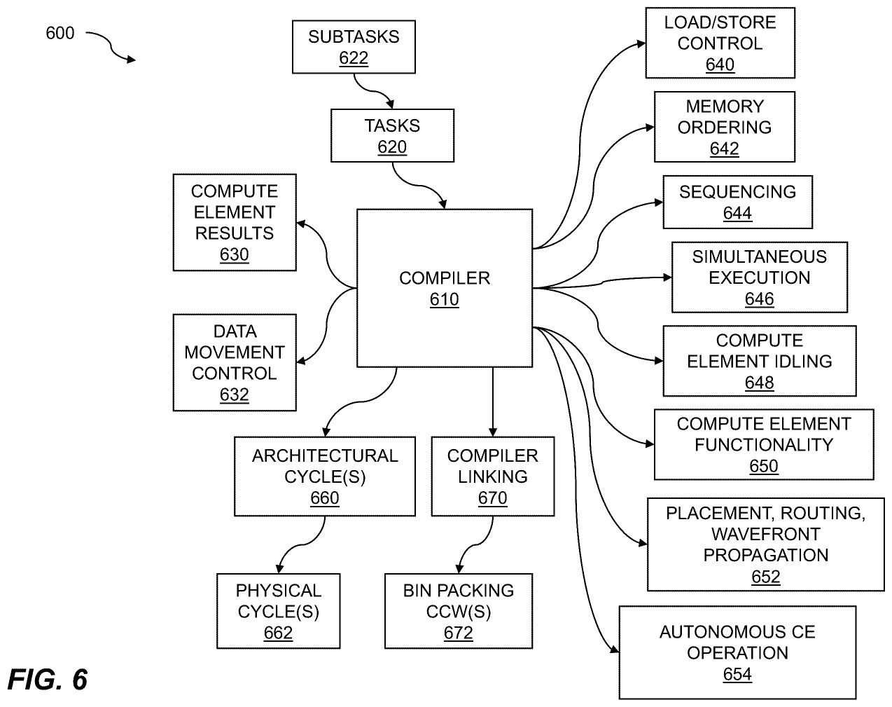

FIG. 6 is a system block diagram for compiler interactions. Discussed throughout, compute elements within a 2D array are known to a compiler which can compile tasks and subtasks for execution on the array. The compiled tasks and subtasks comprise operations which can be executed on one or more compute elements within the 2D array. The compiled tasks and subtasks are executed to accomplish task processing. A variety of interactions, such as placement of tasks, routing of data, and so on, can be associated with the compiler. The compiler interactions enable a parallel processing architecture with bin packing. A two-dimensional (2D) array of compute elements is accessed, wherein each compute element within the array of compute elements is known to a compiler and is coupled to its neighboring compute elements within the array of compute elements. A plurality of compressed control words is generated by the compiler, wherein the plurality of control words enables compute element operation and compute element memory access, and wherein the plurality of compressed control words is operationally sequenced. The plurality of compressed control words is linked by the compiler, wherein linking information is contained in at least one field of each of the plurality of compressed control words. The plurality of compressed control words is loaded into a control word cache coupled to the array of compute elements, wherein the plurality of compressed control words is loaded into the control word cache in an operationally non-sequenced order. The plurality of compressed control words is ordered into an operationally sequenced execution order, based on the linking information.

The system block diagram 600 includes a compiler 610. The compiler can include a high-level compiler such as a C, C++, Python, or similar compiler. The compiler can include a compiler implemented for a hardware description language such as a VHDL™ or Verilog™ compiler. The compiler can include a compiler for a portable, language-independent, intermediate representation such as low-level virtual machine (LLVM) intermediate representation (IR). The compiler can generate a set of directions that can be provided to the computer elements and other elements within the array. The compiler can be used to compile tasks 620. The tasks can include a plurality of tasks associated with a processing task. The tasks can further include a plurality of subtasks 622. The tasks can be based on an application such as a video processing or audio processing application. In embodiments, the tasks can be associated with machine learning functionality. The compiler can generate directions for handling compute element results 630. The compute element results can include results derived from arithmetic, vector, array, and matrix operations; Boolean operations; and so on. In embodiments, the compute element results are generated in parallel in the array of compute elements. Parallel results can be generated by compute elements, where the compute elements can share input data, use independent data, and the like. The compiler can generate a set of directions that controls data movement 632 for the array of compute elements. The control of data movement can include movement of data to, from, and among compute elements within the array of compute elements. The control of data movement can include loading and storing data, such as temporary data storage, during data movement. In other embodiments, the data movement can include intra-array data movement.

As with a general-purpose compiler used for generating tasks and subtasks for execution on one or more processors, the compiler 610 can provide directions for task and subtasks handling, input data handling, intermediate and result data handling, and so on. The directions can include one or more operations, where the one or more operations can be executed by one or more compute elements within the array of compute elements. The compiler can further generate directions for configuring the compute elements, storage elements, control units, ALUs, and so on, associated with the array. As previously discussed, the compiler generates directions for data handling to support the task handling. In the system block diagram, the data movement can include loads and stores 640 with a memory array. The loads and stores can include handling various data types such as integer, real or float, double-precision, character, and other data types. The loads and stores can load and store data into local storage such as registers, register files, caches, and the like. The caches can include one or more levels of cache such as a level 1 (L1) cache, level 2 (L2) cache, level 3 (L3) cache, and so on. The loads and stores can also be associated with storage such as shared memory, distributed memory, etc. In addition to the loads and stores, the compiler can handle other memory and storage management operations including memory precedence. In the system block diagram, the memory access precedence can enable ordering of memory data 642. Memory data can be ordered based on task data requirements, subtask data requirements, and so on. The memory data ordering can enable parallel execution of tasks and subtasks.

In the system block diagram 600, the ordering of memory data can enable compute element result sequencing 644. In order for task processing to be accomplished successfully, tasks and subtasks must be executed in an order that can accommodate task priority, task precedence, a schedule of operations, and so on. The memory data can be ordered such that the data required by the tasks and subtasks can be available for processing when the tasks and subtasks are scheduled to be executed. The results of the processing of the data by the tasks and subtasks can therefore be ordered to optimize task execution, to reduce or eliminate memory contention conflicts, etc. The system block diagram includes enabling simultaneous execution 646 of two or more potential compiled task outcomes based on the set of directions. The code that is compiled by the compiler can include branch points, where the branch points can include computations or flow control. Flow control transfers program execution to a different sequence of control words. Since the result of a branch decision, for example, is not known a priori, the initial operations associated with both paths are encoded in the currently executing control word stream. When the correct result of the branch is determined, then the sequence of control words associated with the correct branch result continues execution, while the operations for the branch path not taken are halted and side effects may be flushed. In embodiments, the two or more potential branch paths can be executed on spatially separate compute elements within the array of compute elements.

The system block diagram includes compute element idling 648. In embodiments, the set of directions from the compiler can idle an unneeded compute element within a row of compute elements located in the array of compute elements. Not all of the compute elements may be needed for processing, depending on the tasks, subtasks, and so on that are being processed. The compute elements may not be needed simply because there are fewer tasks to execute than there are compute elements available within the array. In embodiments, the idling can be controlled by a single bit in the control word generated by the compiler. In the system block diagram, compute elements within the array can be configured for various compute element functionalities 650. The compute element functionality can enable various types of compute architectures, processing configurations, and the like. In embodiments, the set of directions can enable machine learning functionality. The machine learning functionality can be trained to process various types of data such as image data, audio data, medical data, etc. In embodiments, the machine learning functionality can include neural network implementation. The neural network can include a convolutional neural network, a recurrent neural network, a deep learning network, and the like. The system block diagram can include compute element placement, results routing, and computation wave-front propagation 652 within the array of compute elements. The compiler can generate directions or instructions that can place tasks and subtasks on compute elements within the array. The placement can include placing tasks and subtasks based on data dependencies between or among the tasks or subtasks, placing tasks that avoid memory conflicts or communications conflicts, etc. The directions can also enable computation wave-front propagation. Computation wave-front propagation can implement and control how execution of tasks and subtasks proceeds through the array of compute elements. The system block diagram 600 can include autonomous compute element (CE) operation 654. As described throughout, autonomous CE operation enables one or more operations to occur outside of direct control word management.

In the system block diagram, the compiler can control architectural cycles 660. An architectural cycle can include an abstract cycle that is associated with the elements within the array of elements. The elements of the array can include compute elements, storage elements, control elements, ALUs, and so on. An architectural cycle can include an “abstract” cycle, where an abstract cycle can refer to a variety of architecture level operations such as a load cycle, an execute cycle, a write cycle, and so on. The architectural cycles can refer to macro-operations of the architecture rather than to low level operations. One or more architectural cycles are controlled by the compiler. Execution of an architectural cycle can be dependent on two or more conditions. In embodiments, an architectural cycle can occur when a control word is available to be pipelined into the array of compute elements and when all data dependencies are met. That is, the array of compute elements does not have to wait for either dependent data to load or for a full memory queue to clear. In the system block diagram, the architectural cycle can include one or more physical cycles 662. A physical cycle can refer to one or more cycles at the element level required to implement a load, an execute, a write, and so on. In embodiments, the set of directions can control the array of compute elements on a physical cycle-by-cycle basis. The physical cycles can be based on a clock such as a local, module, or system clock, or some other timing or synchronizing technique. In embodiments, the physical cycle-by-cycle basis can include an architectural cycle. The physical cycles can be based on an enable signal for each element of the array of elements, while the architectural cycle can be based on a global, architectural signal. In embodiments, the compiler can provide, via the control word, valid bits for each column of the array of compute elements, on the cycle-by-cycle basis. A valid bit can indicate that data is valid and ready for processing, that an address such as a jump address is valid, and the like. In embodiments, the valid bits can indicate that a valid memory load access is emerging from the array. The valid memory load access from the array can be used to access data within a memory or storage element. In other embodiments, the compiler can provide, via the control word, operand size information for each column of the array of compute elements. Various operand sizes can be used. In embodiments, the operand size can include bytes, half-words, words, and double-words.

The system block diagram 600 includes compiler linking 670. The compiler can be used to link the plurality of compressed control words. The linking can include a value, where the value can include an address, a relative address, an offset, a pointer, and so on. The linking can be accomplished using a list such as a linked list. The linked list comprises a pointer to the next operation within a sequence of operations. The linking can indicate an order of execution for two or more operations associated with one or more compressed control words that can be decompressed prior to execution. The linking information is contained in at least one field of each of the plurality of compressed control words. The linking information can indicate an operationally sequenced order of execution of one or more operations associated with one or more compressed control words. The linked plurality of compressed control words can be loaded into storage such as a control word cache. The control word cache can be coupled to the array of compute elements. Since linking information is provided by the compiler, the order in which the control words are stored can include an operationally sequenced order or an operatically non-sequenced order. Thus, the compressed control words can be stored in a storage-efficient manner, even if that storage-efficient manner stores the compressed control words “out of order”. In the block diagram 600, the compressed control words can be “bin packed” 672. In embodiments, the linking information can enable bin packing in the control word cache. That is, the compressed control words can be bin packed into the control word cache. Since the compressed control words can comprise variable length compressed control words, compressed control words of varying sizes can be packed into an amount of storage such as a cache line. The bin packing maximizes storage efficiency while minimizing storage fragmentation. The storage fragmentation can include portions of storage that do not contain data because the portions of storage are too small to hold any of the compressed control words.

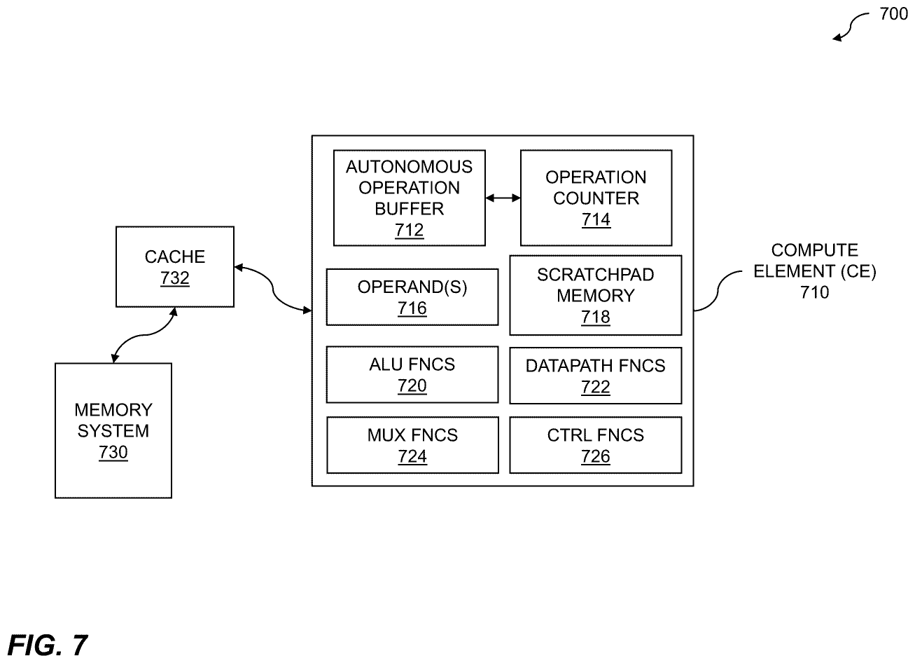

FIG. 7 is a system block diagram for a compute element. The compute element can represent a compute element within an array such as a two-dimensional array of compute elements. The array of compute elements can be configured to perform a variety of operations such as arithmetic, logical, matrix, and tensor operations. The array of compute elements can be configured to perform higher level processing operations such as video and processing operations, natural language processing operations, and so on. The array can be further configured for machine learning functionality, where the machine learning functionality can include a neural network implementation. One or more compute elements can be configured for a parallel processing architecture with bin packing. A two-dimensional (2D) array of compute elements is accessed, wherein each compute element within the array of compute elements is known to a compiler and is coupled to its neighboring compute elements within the array of compute elements. A plurality of compressed control words is generated by the compiler, wherein the plurality of control words enables compute element operation and compute element memory access, and wherein the plurality of compressed control words is operationally sequenced. The plurality of compressed control words is generated by the compiler, wherein linking information is contained in at least one field of each of the plurality of compressed control words. The plurality of compressed control words is loaded into a control word cache coupled to the array of compute elements, wherein the plurality of compressed control words is loaded into the control word cache in an operationally non-sequenced order. The plurality of compressed control words is ordered into an operationally sequenced execution order, based on the linking information.

The system block diagram 700 can include a compute element (CE) 710. The compute element can be configured by providing control in the form of control words, where the control words are generated by a compiler. The compiler can include a high-level language compiler, a hardware description language compiler, and so on. The compute element can include one or more components, where the components can enable or enhance operations executed by the compute element. The system block diagram 700 can include an autonomous operation buffer 712. The autonomous operation buffer can include at least two operations contained in one or more control words. The at least two operations can result from compilation by the compiler of code to perform a task, a subtask, a process, and so on. The at least two operations can be obtained from memory, loaded when the 2-D array of compute elements is scheduled, and the like. The operations can include one or more fields, where the fields can include an operation field, one or more or more operands, and so on. In embodiments, the system block diagram can further include additional autonomous operation buffers. The additional operation buffers can include at least two operations. The operations can be substantially similar to the operations loaded in the autonomous operation buffer or can be substantially different from the operations loaded in the autonomous operation buffer. In embodiments, the autonomous operation buffer contains sixteen operational entries.

The system block diagram can include an operation counter 714. The operation counter can act as a counter such as a program counter to keep track of which operation within the autonomous operation buffer is the current operation. In embodiments, the compute element operation counter can track cycling through the autonomous operation buffer. Cycling through the autonomous operation buffer can accomplish iteration, repeated operations, and so on. In embodiments, additional operation counters can be associated with the additional autonomous operation buffers. In embodiments, an operation in the autonomous operation buffer or in one or more of the additional autonomous operation buffers can comprise one or more operands 716, one or more data addresses for a memory such as a scratchpad memory, and the like. The operand can include an operation that performs various computational tasks, such as a read-modify-write operation. A read-modify-write operation can include arithmetic operations; logical operations; array, matrix, and tensor operations; and so on. The block diagram 700 can include a scratchpad memory 718. The operand can be used to perform an operation on the contents of the scratchpad memory. Discussed below, the contents of the scratchpad memory can be obtained from a cache 732, local storage, remote storage, and the like. The scratchpad memory elements can include register files, which can include one or more 2R1 W register files. The one or more 2R1 W register files can be located within one compute element. The compute element can further include components for performing various functions. The block diagram 700 can include arithmetic logic unit (ALU) functions 720, which can include logical functions. The arithmetic functions can include multiplication, division, addition, subtraction, maximum, minimum, average, etc. The logical functions can include AND, OR, NAND, NOR, XOR, XNOR, NOT, SHIFT, and other logical operations. In embodiments, the logical functions and the mathematical functions can be accomplished using a component such as an arithmetic logic unit (ALU).

A compute element such as compute element 710 can communicate with one or more additional compute elements. The compute elements can be colocated within a 2D array of compute elements, such as the compute element 710, or can be located in other arrays. The compute element can further be in communication with additional elements and components such as with local storage, with remote storage, and so on. The block diagram 700 can include datapath functions 722. The datapath functions can control the flow of data through a compute element, the flow of data between the compute element and other components, and so. The datapath functions can control communications between and among compute elements within the 2D array. The communications can be accomplished using a bus such as an industry standard bus, a ring bus, a network such as a wired or wireless computer network, etc. The block diagram 700 can include multiplexer MUX functions 724. The multiplexer, which can include a distributed MUX, can be controlled by the MUX functions. In embodiments, the ring bus can be implemented as a distributed MUX. The block diagram 700 can include control functions 726. The control functions can be used to configure or schedule one or more compute elements within the 2D array of compute elements. The control functions can enable one or more compute elements, disable one or more compute elements, and so on. A compute element can be enabled or disabled based on whether the compute element is needed for an operation within a given control cycle.

The contents of registers, operands, requested data, and so on, can be obtained from various types of storage. In the block diagram 700, the contents can be obtained from a memory system 730. The memory system can be shared among compute elements within the 2D array of compute elements. The memory system can be included within the 2D array of compute elements, coupled to the array, located remotely from the array, etc. The memory system can include a high-speed memory system. Contents of the memory system, such as requested data, can be loaded into one or more caches 732. The one or more caches can be coupled to a compute element, a plurality of compute elements, and so on. The caches can include multilevel caches (discussed below), such as L1, L2, and L3 caches. Other memory or storage can be coupled to the compute element.

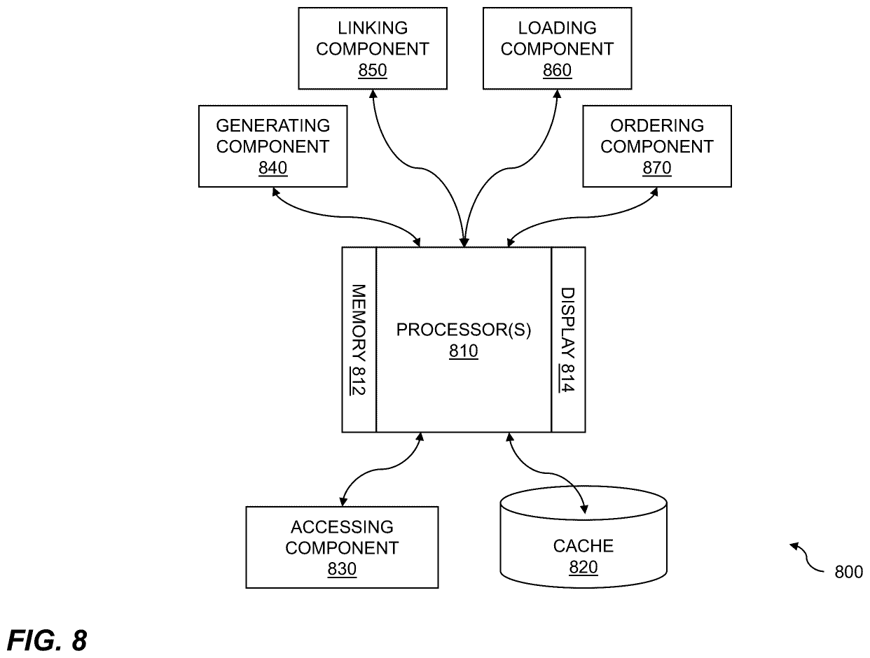

FIG. 8 is a system diagram for parallel processing. The parallel processing is enabled by a parallel processing architecture with bin packing. The system 800 can include one or more processors 810, which are attached to a memory 812 which stores instructions. The system 800 can further include a display 814 coupled to the one or more processors 810 for displaying data; access rewrites; intermediate steps; directions; control words; compressed control words; control words implementing Very Long Instruction Word (VLIW) functionality; topologies including systolic, vector, cyclic, spatial, streaming, or VLIW topologies; and so on. In embodiments of computer system 800, one or more processors 810 are coupled to the memory 812, wherein the one or more processors, when executing the instructions which are stored, are configured to: access an array of compute elements, wherein each compute element within the array of compute elements is known to a compiler and is coupled to its neighboring compute elements within the array of compute elements; generate a plurality of compressed control words by the compiler, wherein the plurality of control words enables compute element operation and compute element memory access, and wherein the plurality of compressed control words is operationally sequenced; link the plurality of compressed control words, by the compiler, wherein linking information is contained in at least one field of each of the plurality of compressed control words; load the plurality of compressed control words into a control word cache coupled to the array of compute elements, wherein the plurality of compressed control words is loaded into the control word cache in an operationally non-sequenced order; and order the plurality of compressed control words into an operationally sequenced execution order, based on the linking information. The plurality of compressed control words is decompressed. Operations are executed within the array of compute elements using the plurality of compressed control words that were decompressed. The compute elements can include compute elements within one or more integrated circuits or chips; compute elements or cores configured within one or more programmable chips such as application specific integrated circuits (ASICs); field programmable gate arrays (FPGAs); heterogeneous processors configured as a mesh; standalone processors; etc.

The system 800 can include a cache 820. The cache 820 can be used to store data such as bin packed compressed control words, directions to compute elements, decompressed control words, compute element operations associated with decompressed control words, intermediate results, microcode, branch decisions, and so on. The cache can comprise a small, local, easily accessible memory available to one or more compute elements. In embodiments, the data that is stored within the cache can include compressed control words loaded into a control word cache in an operationally non-sequenced order, linking information, compressed control words ordered into an operationally sequenced execution order, based on the linking information, etc. Embodiments include storing relevant portions of a control word within the cache associated with the array of compute elements. The cache can be accessible to one or more compute elements. The cache, if present, can include a dual read, single write (2R1 W) cache. That is, the 2R1 W cache can enable two read operations and one write operation contemporaneously without the read and write operations interfering with one another.

The system 800 can include an accessing component 830. The accessing component 830 can include control logic and functions for accessing a two-dimensional (2D) array of compute elements. Each compute element within the array of compute elements is known to a compiler and is coupled to its neighboring compute elements within the array of compute elements. A compute element can include one or more processors, processor cores, processor macros, and so on. Each compute element can include an amount of local storage. The local storage may be accessible to one or more compute elements. Each compute element can communicate with neighbors, where the neighbors can include nearest neighbors or more remote “neighbors”. Communication between and among compute elements can be accomplished using a bus such as an industry standard bus, a ring bus, a network such as a wired or wireless computer network, etc. In embodiments, the ring bus is implemented as a distributed multiplexor (MUX).

The system 800 can include a generating component 840. The generating component 840 can include control and functions for generating a plurality of compressed control words by the compiler. The plurality of control words enables compute element operation and compute element memory access. The plurality of compressed control words is operationally sequenced. The control words can be used to control compute element operation and compute element memory access on a cycle-by-cycle basis. The control words can include fixed-length control words. However, when even fixed-width control words are compressed, the resulting compressed control words can be of varying lengths. This also can occur when the plurality of compressed control words include variable length control words. The variable length control words, whether resulting from control word architecture or compression, do not generally enable alignment with cache line boundaries, storage address edges, and so on. The control words can be based on low-level control words such as assembly language words, microcode words, firmware words, and so on. Variable length control words can enable control such that a different number of operations for a differing plurality of compute elements can be conveyed in each control word.

The control of the array of compute elements on a cycle-by-cycle basis can include configuring the array to perform various compute operations. In embodiments, the stream of wide control words comprises variable length control words generated by the compiler. In embodiments, the stream of wide, variable length control words generated by the compiler provides direct fine-grained control of the 2D array of compute elements. The compute operations can include a read-modify-write operation. The compute operations can enable audio or video processing, artificial intelligence processing, machine learning, deep learning, and the like. The providing control can be based on microcode control words, where the microcode control words can include opcode fields, data fields, compute array configuration fields, etc. The compiler that generates the control can include a general-purpose compiler, a parallelizing compiler, a compiler optimized for the array of compute elements, a compiler specialized to perform one or more processing tasks, and so on. The providing control can implement one or more topologies such as processing topologies within the array of compute elements. In embodiments, the topologies implemented within the array of compute elements can include a systolic, a vector, a cyclic, a spatial, a streaming, or a Very Long Instruction Word (VLIW) topology. Other topologies can include a neural network topology. The control can enable machine learning functionality for the neural network topology.

The system block diagram 800 can include a linking component 850. The linking component 850 can include control and functions for linking the plurality of compressed control words, by the compiler, wherein linking information is contained in at least one field of each of the plurality of compressed control words. The linking information can be used to determine an order of execution for the compressed control words. The linking information can include a value such as an offset value, where the offset value can include a number of bytes, words, and so on between a compressed control word and a next compressed control word. The byte offset to the next compressed control word can comprise a linked list pointer. In embodiments, the linking information can enable bin packing in the control word cache. Recall that the bin packing can accomplish storage of the compressed control words in an out-of-order or operationally non-sequenced order to reduce the amount of storage required to store the compressed control words. The storage can include cache storage. In embodiments, the linking information can enable bin packing in the control word cache. The offset associated with the linking information can be used to prefetch a next compressed control word. In embodiments, the offset can accomplish “run ahead” fetch walking for prefetching compressed control words, prefetching two or more paths of a conditional branch, etc.

The system 800 can include a loading component 860. The loading component 860 can include control and functions for loading the plurality of compressed control words into a control word cache coupled to the array of compute elements, wherein the plurality of compressed control words is loaded into the control word cache in an operationally non-sequenced order. The non-sequential order can result from a first fit, best fit, or other technique that can be used to load a number of compressed control words within a minimum amount of storage such as cache storage. The loading compressed control words can be based on word boundaries, cache line boundaries, a number of bytes such as 512 bytes, and so on. The loading can be based on minimizing storage fragmentation, where fragmentation can include unused storage (e.g., storage not used to store one or more compressed control words) within cache lines, words, storage blocks, etc.

The system 800 can include an ordering component 870. The ordering component 870 can include control and functions for ordering the plurality of compressed control words into an operationally sequenced execution order, based on the linking information. The linking information can be used as a pointer, such as a linked list pointer, to point to the next compressed control word in order of execution. The ordering can include shifting. The shifting can realign a compressed control word with a cache line boundary, a word boundary, and so on. The shifting can be accomplished using a simplified shifter, where the simplified shifter can include a shift-left shifter. In the case that a compressed control word is already aligned with a cache line, word, etc. boundary, then the shift-left shift operation can be bypassed. In embodiments, the ordering can be performed on the plurality of compressed control words that were loaded from control word cache. The ordering the compressed control words can include aligning each compressed control word with a cache line border and ordering the compressed control words into their operational sequence. In embodiments, the plurality of compressed control words can be loaded into the control word cache using a fixed frame format. A frame can include one or more compressed control words. In embodiments, the fixed frame format can encompass the plurality of compressed control words. The frame format for storing the compressed control words can be significantly less storage efficient than the storing the bin packed compressed control words. In embodiments, the fixed frame format can include unused space between at least two of the plurality of compressed control words. The unused space between at least two compressed control words can result in storage fragmentation.

Further embodiments include decompressing the plurality of compressed control words. The decompressing the compressed control words can include enabling or disabling individual compute elements, rows or columns of compute elements, regions of compute elements, and so on. The decompressed control words can include one or more compute element operations. Further embodiments include executing operations within the array of compute elements using the plurality of compressed control words that were decompressed. The order in which the operations are executed is critical to successful processing such as parallel processing. In embodiments, the decompressor can operate on compressed control words that were ordered before they are presented to the array of compute elements. The operations that can be performed can include arithmetic operations, Boolean operations, matrix operations, neural network operations, and the like. The operations can be executed based on the control words generated by the compiler. The control words can be provided to a control unit, where the control unit can control the operations of the compute elements within the array of compute elements. Operation of the compute elements can include configuring the compute elements, providing data to the compute elements, routing and ordering results from the compute elements, and so on. In embodiments, the same decompressed control word can be executed on a given cycle across the array of compute elements. The control words can be decompressed to provide control on a per compute element basis, where each control word can be comprised of a plurality of compute element control groups or bunches. One or more control words can be stored in a compressed format within a memory such as a cache. The compression of the control words can greatly reduce storage requirements. In embodiments, the control unit can operate on decompressed control words. The executing operations contained in the control words can include distributed execution of operations. In embodiments, the distributed execution of operations can occur in two or more compute elements within the array of compute elements. Recall that the mapping of the virtual registers can include renaming by the compiler. In embodiments, the renaming can enable the compiler to orchestrate execution of operations using the physical register files.

The system 800 can include a computer program product embodied in a non-transitory computer readable medium for parallel processing, the computer program product comprising code which causes one or more processors to perform operations of: accessing an array of compute elements, wherein each compute element within the array of compute elements is known to a compiler and is coupled to its neighboring compute elements within the array of compute elements; generating a plurality of compressed control words by the compiler, wherein the plurality of control words enables compute element operation and compute element memory access, and wherein the plurality of compressed control words is operationally sequenced; linking the plurality of compressed control words, by the compiler, wherein linking information is contained in at least one field of each of the plurality of compressed control words; loading the plurality of compressed control words into a control word cache coupled to the array of compute elements, wherein the plurality of compressed control words is loaded into the control word cache in an operationally non-sequenced order; and ordering the plurality of compressed control words into an operationally sequenced execution order, based on the linking information.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams, show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A processor-implemented method for parallel processing comprising:
accessing an array of compute elements, wherein each compute element within the array of compute elements is known to a compiler and is coupled to its neighboring compute elements within the array of compute elements;
generating a plurality of compressed control words by the compiler, wherein the plurality of control words enables compute element operation and compute element memory access, and wherein the plurality of compressed control words is operationally sequenced;
linking the plurality of compressed control words, by the compiler, wherein linking information is contained in at least one field of each of the plurality of compressed control words;
loading the plurality of compressed control words into a control word cache coupled to the array of compute elements, wherein the plurality of compressed control words is loaded into the control word cache in an operationally non-sequenced order; and
ordering the plurality of compressed control words into an operationally sequenced execution order, based on the linking information.

2. The method of claim 1 further comprising decompressing the plurality of compressed control words.

3. The method of claim 2 further comprising executing operations within the array of compute elements using the plurality of compressed control words that were decompressed.

4. The method of claim 2 wherein the decompressing operates on compressed control words that were ordered before they are presented to the array of compute elements.

5. The method of claim 1 further comprising aligning the plurality of compressed control words.

6. The method of claim 5 wherein the aligning is accomplished using a shift register.

7. The method of claim 6 further comprising bypassing the shift register for a compressed control word that is already aligned.

8. The method of claim 1 wherein the ordering is performed on the plurality of compressed control words that were loaded from the control word cache.

9. The method of claim 8 wherein the plurality of compressed control words is loaded into the control word cache using a fixed frame format.

10. The method of claim 9 wherein the fixed frame format encompasses the plurality of compressed control words.

11. The method of claim 10 wherein the fixed frame format includes unused space between at least two of the plurality of compressed control words.

12. The method of claim 1 wherein the linking information enables bin packing in the control word cache.

13. The method of claim 1 further comprising an autonomous operation buffer in at least one of the compute elements of the array of compute elements.

14. The method of claim 13 further comprising a compute element operation counter coupled to the autonomous operation buffer.

15. The method of claim 14 wherein the autonomous operation buffer and the compute element operation counter enable compute element operation execution.

16. The method of claim 15 wherein the compute element operation execution involves operations not explicitly specified in a control word.

17. The method of claim 1 wherein a field of a control word in the plurality of control words signifies a repeat last operation control word.

18. The method of claim 1 wherein the plurality of compressed control words comprises variable length control words.

19. The method of claim 1 wherein the array of compute elements comprises a two-dimensional array of compute elements.

20. The method of claim 19 wherein the two-dimensional array of compute elements is stacked to form a three-dimensional array.

21. The method of claim 20 wherein the three-dimensional array is physically stacked.

22. The method of claim 20 wherein the three-dimensional array is logically stacked.

23. A computer program product embodied in a non-transitory computer readable medium for parallel processing, the computer program product comprising code which causes one or more processors to perform operations of:
accessing an array of compute elements, wherein each compute element within the array of compute elements is known to a compiler and is coupled to its neighboring compute elements within the array of compute elements;
generating a plurality of compressed control words by the compiler, wherein the plurality of control words enables compute element operation and compute element memory access, and wherein the plurality of compressed control words is operationally sequenced;
linking the plurality of compressed control words, by the compiler, wherein linking information is contained in at least one field of each of the plurality of compressed control words;
loading the plurality of compressed control words into a control word cache coupled to the array of compute elements, wherein the plurality of compressed control words is loaded into the control word cache in an operationally non-sequenced order; and
ordering the plurality of compressed control words into an operationally sequenced execution order, based on the linking information.

24. A computer system for parallel processing comprising:
a memory which stores instructions;
one or more processors coupled to the memory, wherein the one or more processors, when executing the instructions which are stored, are configured to:
access an array of compute elements, wherein each compute element within the array of compute elements is known to a compiler and is coupled to its neighboring compute elements within the array of compute elements;
generate a plurality of compressed control words by the compiler, wherein the plurality of control words enables compute element operation and compute element memory access, and wherein the plurality of compressed control words is operationally sequenced;
link the plurality of compressed control words, by the compiler, wherein linking information is contained in at least one field of each of the plurality of compressed control words;
load the plurality of compressed control words into a control word cache coupled to the array of compute elements, wherein the plurality of compressed control words is loaded into the control word cache in an operationally non-sequenced order; and
order the plurality of compressed control words into an operationally sequenced execution order, based on the linking information.
